(19) United States
(12) Patent Application Publication
(10) Pub. No.: US 2010/0200053 A1
(43) Pub. Date: Aug. 12, 2010

(54) PHOTOVOLTAIC DEVICE HAVING A PROTECTIVE LAYER AND METHODS FOR MANUFACTURING THAT DEVICE

(75) Inventors: Uday Varde, West Bloomfield, MI (US); Casimir Kotarba, III, Farmington Hills, MI (US); Jonathan Call, Royal Oak, MI (US)

Correspondence Address: GIFFORD, KRASS, SPRINKLE,ANDERSON & CITKOWSKI, P.C, PO BOX 7021, TROY, MI, 48007-7021, US

(73) Assignee: United Solar Ovonic LLC, Auburn Hills, MI (US)

(21) Appl. No.: 12/560,781

(22) Filed: Sep. 16, 2009

Related U.S. Application Data
(60) Provisional application No. 61/097,384, filed on Sep. 16, 2008.

(51) Int. Cl. H01L 31/0203; H01L 31/18

(52) U.S. Cl. 136/256; 438/64; 257/E31.117

(57) ABSTRACT

Disclosed herein is a method of making a photovoltaic device having a protective layer affixed to a top surface thereof. The protective layer is comprised of a polymeric material having a fluorinated first surface and a second, opposed, surface which is non-fluorinated or less fluorinated. The protective layer is affixed to the photovoltaic device so that the first surface is farthest therefrom. In some instances, the fluorination may extend to edge portions of the protective layer as well as to any intermediate layers. Further disclosed are devices which incorporate the fluorinated protective layers.

### CROSS-REFERENCE TO RELATED APPLICATIONS

This application claims priority of U.S. Provisional Patent Application Ser. No. 61/097,384 filed Sep. 16, 2008, the disclosure of which is incorporated herein by reference.

### FIELD OF THE INVENTION

This invention relates generally to photovoltaic devices. More specifically, the invention relates to photovoltaic devices having a protective layer comprised of a polymeric material having an at least partially fluorinated surface.

### BACKGROUND OF THE INVENTION

Photovoltaic devices are often provided with a protective layer, also known as a superstrate, typically disposed upon at least the light-incident (top) surface thereof. This layer must be transparent and durable. In many instances, the protective layer is formed from a body of a fluoropolymer such as ethylene-tetrafluoroethylene (ETFE). Such fluorinated materials are attractive since they are chemically inert and therefore resistant to degradation under harsh atmospheric conditions typically encountered by photovoltaic devices. Such fluorinated materials also have a low surface energy; hence they are inherently self-cleaning.

There are some problems associated with the use of bulk fluorinated materials such as ETFE for the protective layer of a photovoltaic device. These materials are expensive. Furthermore, these materials, because of their low surface energy, exhibit poor adhesion to other materials. Therefore, the affixation of bulk fluorinated materials to photovoltaic devices can be difficult, and typically requires the use of special techniques which may include pretreatment steps such as flame treatment, plasma treatment, chemical etching, the use of surface primers, etc. In addition to being complex, these steps further increase the expense of the production of the photovoltaic devices.

### BRIEF DESCRIPTION OF THE INVENTION

Disclosed herein is a method of making an electronic device such as a photovoltaic device having a protective layer affixed thereto. According to the method, a protective layer comprised of a first polymeric material, which is essentially non-fluorinated, is provided, and that protective layer is subjected to a fluorinating process so that a first surface thereof is a fluorinated surface characterized by the presence of a plurality of carbon-fluorine (C—F) bonds thereupon. The protective layer is affixed to the device so that the fluorinated surface thereof is farthest from the device. In particular instances, the device is a photovoltaic device. The step of affixing the protective layer to the device may be carried out before the step of fluorinating, while in other instances the layer is first fluorinated and then affixed. In specific instances, the polymeric material of the protective layer is transparent and may be selected from the group consisting of: acrylic polymers, olefinic polymers, polyesters, ionomers, polyurethanes, polycarbonates, polyamides, and various combinations of the foregoing.

In some instances, one or more intermediate layers may be disposed between the protective layer and the device. The intermediate layer may, in some instances, be comprised of one or more of ethylene vinyl acetate, polyvinyl butyral, a silicone, or a polyurethane.

In particular instances, the step of fluorinating the protective layer is carried out so that a second surface of the protective layer, which is opposed to the first surface, is a non-fluorinated surface characterized by the absence of any C—F bonds thereupon or by a level of C—F bonds thereupon which is less than the level of C—F bonds upon the first surface. In some instances, the step of fluorinating may be carried out so that one or more edge surfaces of a multi-layer material construction is fluorinated, thereby acting as a hydrophobic barrier in order to minimize edge-based water ingress.

Further disclosed herein is a photovoltaic device having a protective layer disposed thereupon wherein the protective layer is comprised of a body of polymeric material having a first surface characterized by the presence of a first percentage of C—F bonds thereupon and having a first surface energy. The body of polymeric material has a second surface, opposed to the first surface, wherein the second surface is characterized by a second percentage of C—F bonds thereupon which is less than the first percentage of C—F bonds. The second surface has a second surface energy which is greater than the first surface energy. This protective layer is disposed on the photovoltaic device so that the second surface is closest to the light-incident surface of the photovoltaic device and the first surface of the protective layer is farthest from the photovoltaic device.

### BRIEF DESCRIPTION OF THE DRAWINGS

FIG. 1 is a cross-sectional view of a generalized photovoltaic device illustrating the principles of the present invention;

FIG. 2 is a cross-sectional view of another generalized photovoltaic device illustrating the principles of the present invention as implemented in connection with an intermediate layer; and

FIG. 3 is a cross-sectional view of a portion of a photovoltaic device generally similar to that of FIG. 2 further illustrating the fluorination of edge portions thereof.

### DETAILED DESCRIPTION OF THE INVENTION

The present invention provides photovoltaic devices which incorporate a protective layer comprising a sheet of polymeric material having opposed surfaces with distinctly different surface properties. In the context of this disclosure, the element referred to as the photovoltaic (PV) cell, or photovoltaic device, may be of any configuration and material known in the art; and it is to be understood that a PV cell may include a plurality of individual photovoltaic units stacked or arranged in various configurations, including multijunction configurations. Also, it is to be understood that PV devices may include current collecting grid structures, reflective layers, texturizing layers, substrates and the like. For purposes of this disclosure, the invention will be described, primarily, with regard to a top protective layer disposed on the light-incident surface of the device; however, it is to be understood that the basic principles may also be used in protective layers disposed on other portions of the photovoltaic device such as its back, non-light-incident surface.

The polymeric material comprising the protective layer of the present invention has a first surface which is characterized by the presence of C—F bonds and a second surface, opposed to the first surface, characterized by a lower level of C—F bonds, and in some instances, an absence of C—F bonds. As such, this surface is referred to herein as being “essentially non-fluorinated”. In general, the C—F bonds will be covalent bonds, which is understood to include bonds having a purely covalent nature as well as bonds having some ionic character. It is to be understood that the present invention is not limited by the electronic nature of the bond formed by the fluorine. This protective layer is affixed to the photovoltaic device so that the first (fluorinated) surface is uppermost, and provides the outer surface of the protected photovoltaic device. The second essentially non-fluorinated surface is affixed (either directly or indirectly) to the photovoltaic device. The dual properties of this protective layer maximize the effectiveness and efficiency of the process.

The fluorinated surface has a low surface energy and is resistant to chemical degradation (from, in terms of nonlimiting examples, acid rain, sulfur, ammonia, and other chemicals found in smog or otherwise part of the environment proximate photovoltaic installations) and is self-cleaning. The essentially non-fluorinated surface is more reactive and may be readily adhered to the photovoltaic device by the use of adhesives, intermediate polymeric layers, melt casting, thermal bonding, pressure bonding and the like.

The bulk material of the protective layer may be comprised of any polymer which is compatible with the photovoltaic device and has desirable properties, which can include, but are not limited to, optical transparency, refractive index, glass transition temperature (Tg), coefficient of thermal expansion (CTE), DC dielectric strength, flame spread characteristics, cut resistance, puncture resistance, abrasion resistance, relative thermal index (RTI), and long-term durability and otherwise good mechanical integrity. In those instances where the protective layer is not disposed on the light-incident surface of the photovoltaic device, transparency and refractive index are not a major concern. Some polymers which may be utilized in the practice of the present invention comprise acrylates such as polymethyl methacrylate (PMMA), olefins such as polyethylene (PE) or polypropylene (PP), polyesters such as polyethylene terephthalate (PET) or polyethylene napthalate (PEN), and other polymers such as polycarbonates, ionomers, polyamides, polyurethanes, and silicon-containing polymers, as well as glass and the like. Various processes for the surface fluorination of such polymers are known in the art and may be readily adapted in the practice of the present invention. For example, U.S. Pat. No. 5,770,135 and published U.S. Patent Application 2005/0282971 disclose processes for the surface fluorination of various polymeric materials. The disclosures of these documents are incorporated herein by reference.

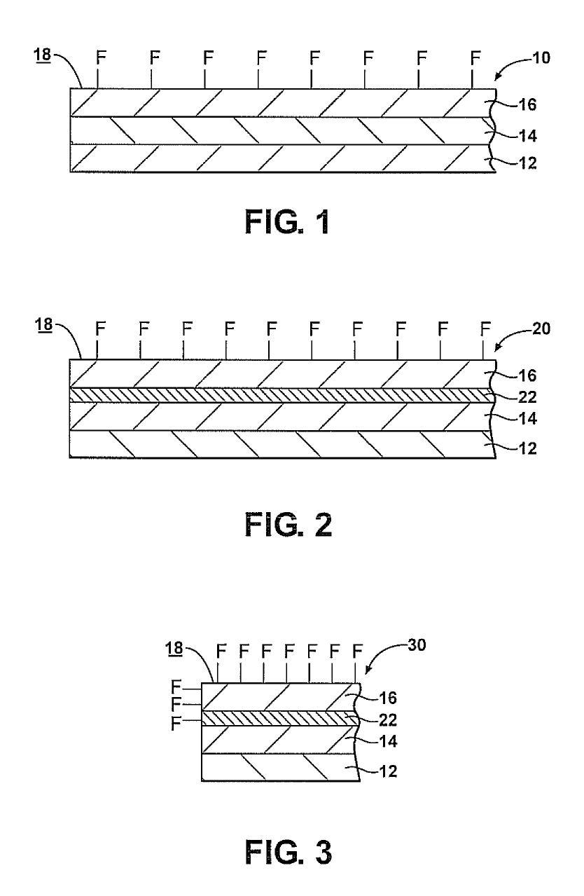

Referring now to FIG. 1, there is shown a schematic depiction of a generalized photovoltaic device 10 in accord with the present invention. This device 10 includes a substrate 12 which, as noted above, may be comprised of a body of metal, polymer, glass, or the like. Disposed upon the substrate 12 is a body of photovoltaic material 14 which may comprise a single photovoltaic cell or a plurality of individual photovoltaic units stacked or arranged in various configurations and further including current collecting grid structures, reflective layers, texturizing layers, electrodes, and the like. Disposed atop the photovoltaic body 14 is a protective layer of polymeric material 16 in accord with the present invention. The polymeric material has a first surface 18 which differs from the remainder of the polymeric material insofar as it includes a number of C—F bonds (shown schematically herein). The presence of these C—F bonds, as noted above, alters the properties of this first surface 18 as compared to the remainder of the material. As also noted above, the remaining portion of the material may, in some instances, include some C—F bonds therein; however, the level of C—F bonds in the bulk of the material and/or the other surfaces of the material are lower than in the first surface 18.

Fluorination of the polymeric material may take place either before or after it is affixed to the photovoltaic device. In one implementation of the invention, a polymeric film material, in sheet, roll or other form, is subjected to a surface fluorination process so that only one surface thereof is fluorinated. This material is then adhered to a photovoltaic device with the fluorinated surface uppermost; that is to say, it is adhered so that the fluorinated surface is farthest from the photovoltaic device.

In another implementation of the invention, the bulk polymeric material of the protective layer is first adhered to the photovoltaic device and then subsequently surface fluorinated. In either instance, adhesion of the layer to the photovoltaic device may be accomplished by various techniques. In one specific instance, an intermediate polymeric bonding layer or an encapsulant is employed. As is known in the art, polymers such as ethylene vinyl acetate (EVA), as well as polyvinyl butyral (PVB), silicones, ionomers, polyurethanes, phenolics, and the like, singly or in combination, may be used as intermediate bonding layers. In other instances, other polymeric materials as well as adhesives, including hot melt adhesives, may be utilized for the bonding. FIG. 2 is a schematic depiction of a photovoltaic device 20, which is generally similar to the device 10 of FIG. 1, but which further includes an intermediate bonding layer 22 interposed between the photovoltaic body 14 and the polymeric layer 16 having the fluorinated surface 18. As will be apparent to those of skill in the art, still other layers or structures may likewise be interposed. In yet other instances, the polymeric layer may be directly bonded to the photovoltaic device by pressure bonding, heat bonding, melt casting, solvent casting, or any other such technique.

While the present invention is described with regard to protective layers having one surface characterized by the presence of C—F bonds and another characterized by the absence of C—F bonds, it is to be understood that in some instances, some degree of fluorination of the second surface may take place (either intentionally or unintentionally) and may be compatible with the practice of the present invention. Specifically, in such instances the first surface will be highly fluorinated so as to cause it to have a low surface energy. The second surface may be somewhat fluorinated; that is to say, some percentage of C—F bonds in smaller number than those on the first surface may be present, provided that the degree of fluorination of the second surface is not sufficiently high so as to impair bonding to the photovoltaic device. Therefore, in the context of this disclosure it is to be understood that the protective layer is characterized in that the surface properties, including surface energy of the two faces of the protective layer, are different and the surface energy of one surface thereof is significantly lower than that of the other surface.

As discussed above, fluorination of the protective layer may take place before or after it is adhered to the photovoltaic device. In some instances, and in particular when fluorination takes place after the affixation of the protective layer, it may be advantageous to allow fluorination of further portions of the device to occur. Referring now to FIG. 3, there is shown an enlarged view of a section of a photovoltaic device 30 which is generally similar to the device 20 of FIG. 2 with regard to its layer construction. In that regard, the device 30 includes a substrate 12, a photovoltaic body 14, a protective layer 16, and an intermediate adhesion layer 22. As in the previous embodiments, the upper surface 18 of the protective layer 16 is fluorinated. However, in the FIG. 3 device, the fluorination process is also implemented with regard to exposed edge portions of the protective layer 16 and, in this instance, the intermediate layer 22. In embodiments of this type, the edge-based fluorination provides further protection for the environmentally exposed segments of those layers, such as providing a hydrophobic barrier in order to minimize edge-based water ingress. In some embodiments, multiple edges of a multi-layer device configuration may be fluorinated. In yet other instances, it may be advantageous to allow the fluorination to take place with regard to exposed edges of the photovoltaic body 14 and/or substrate 12, depending upon the nature of those materials. In some instances, fluorination may be controlled by appropriately masking portions of the device during the fluorination process while in other instances various components of the device, such as the substrate or portions of the photovoltaic body, may be immune to the fluorinating process, and hence no masking will be needed.

While the foregoing invention has been described primarily with regard to photovoltaic devices, it is to be understood that principles thereof may be extended to yet other electronic devices as well as to various other structures where it is desirable to include a protective layer having low surface energy, high transparency, and other desirable physical properties.

In view of the discussion, description and teaching presented herein, various other modifications and variations of the invention will be apparent to those of skill in the art. The foregoing discussion and description are illustrative of specific embodiments of the invention, but are not meant to be limitations upon the practice thereof. It is the following claims, including all equivalents, which define the scope of the invention.

1. A method of making a photovoltaic device having a protective layer affixed thereto, said method comprising the steps of:
providing a photovoltaic device;
providing a protective layer comprised of a first polymeric material characterized in that said first polymeric material is essentially non-fluorinated;
fluorinating said protective layer so that a first surface thereof is a fluorinated surface characterized by the presence of a plurality of C—F bonds thereupon; and
affixing said protective layer to said photovoltaic device; said method further characterized in that said steps of fluorinating and affixing are implemented so that the fluorinated surface of said protective layer is farthest from said photovoltaic device,

2. The method of claim 1, wherein said step of affixing said protective layer to said photovoltaic device is carried out after said step of fluorinating.

3. The method of claim 1, wherein said step of fluorinating said protective layer is carried out after said protective layer is affixed to said photovoltaic device.

4. The method of claim 1, wherein the first polymeric material comprises a transparent polymer.

5. The method of claim 1, wherein said polymer is selected from the group consisting of acrylics, olefinic polymers, polyesters, ionomers, polyurethanes, polycarbonates, polyamides, and combinations thereof.

6. The method of claim 1, wherein said first polymeric material is selected from the group consisting of PMMA, polyethylene, and polycarbonate.

7. The method of claim 1, wherein said polymeric protective material is selected from the group consisting of polymethyl methacrylate (PMMA), polyethylene (PE), polypropylene (PP), polystyrene (PS), polyethylene terephthalate (PET), polyethylene napthalate (PEN), nylon, and polycarbonate.

8. The method of claim 7, wherein said intermediate layer is comprised of a member selected from the group consisting of ethylene vinyl acetate, polyvinyl butyral, a silicone, an ionomer, a polyurethane thermoplastic hot melt adhesives, phenolics, and combinations thereof.

9. The method of claim 1, wherein the step of fluorinating said protective layer is carried out so that a second surface of said protective layer, which is opposed to said first surface, is a non-fluorinated surface characterized by the absence of any C—F bonds thereupon, or by a level of C—F thereupon which is less than the level of C—F bonds upon said first surface.

10. The method of claim 9, wherein the step of fluorinating said protective layer further includes fluorinating an edge surface of said layer, which edge surface extends between said first surface and said second surface so that said edge surface has a level of C—F bonds thereupon which is greater than the level of any C—F bonds on said second surface; whereby said C—F bonds associated with said second surface establish a hydrophobic barrier which impedes edge-based ingress of water in said device.

11. A photovoltaic device having disposed thereupon a protective layer comprised of a body of polymeric material having a first surface characterized by the presence of a first percentage of C—F bonds thereupon, said first surface having a first surface energy; said body of polymeric material having a second surface, opposed to said first surface, said second surface characterized by a second percentage of C—F bonds thereupon, said second percentage being less than said first percentage, said second surface having a second surface energy which is greater than said first surface energy; said protective layer being disposed on said photovoltaic device so that said second surface is closest to the light-incident surface of the photovoltaic device and the first surface of the protective layer is farthest from said photovoltaic device.

12. The photovoltaic device of claim 11, wherein the polymeric material of said protective layer is transparent.

13. The photovoltaic device of claim 11, wherein said polymeric protective material is selected from the group consisting of polymethyl methacrylate (PMMA), polyethylene (PE), polypropylene (PP), polystyrene (PS), polyethylene terephthalate (PET), polyethylene napthalate (PEN), nylon, and polycarbonate.

14. The photovoltaic device of claim 11, further including a second body of polymeric material interposed between the photovoltaic device and the second surface of the protective layer.

15. The photovoltaic device of claim 14, wherein said second body of polymeric material is comprised of a member selected from the group consisting of ethylene vinyl acetate, polyvinyl butyral, a silicone, an ionomer, a polyurethane, a phenolic, and combinations thereof.

16. The photovoltaic device of claim 11, wherein said photovoltaic device includes at least one layer of a hydrogenated silicon alloy material.

17. The photovoltaic device of claim 11, wherein said protective layer includes an edge surface which extends between said opposed first surface and second surface, said edge surface characterized by the presence of a third percentage of C—F bonds thereupon, which third percentage is greater than said second percentage, said edge surface having a third surface energy which is less than said third surface energy; whereby said third percentage of C—F bonds associated with said edge surface establishes a hydrophobic barrier which impedes edge-based ingress of water in said device.

18. A photovoltaic device having a protective layer disposed thereupon, said protective layer having a first surface disposed farthest from said photovoltaic device, said first surface having a first surface energy; said protective layer having a second surface disposed closest to said photovoltaic device, said second surface having a second surface energy winch is greater than said first surface energy.
